(19) United States
(12) Patent Application Publication
(10) Pub. No.: US 2011/0059611 A1
(43) Pub. Date: Mar. 10, 2011

(54) ELECTROLESS DEPOSITION OF BARRIER LAYERS

(75) Inventor: Raimund Mellies, Dieburg (DE)

(73) Assignee: BASF SE, LUDWIGSHAFEN (DE)

(21) Appl. No.: 12/863,114

(22) PCT Filed: Jan. 20, 2009
(86) PCT No.: PCT/EP09/50589

§ 371 Date: Jul. 15, 2010

(30) Foreign Application Priority Data
Jan. 24, 2008 (EP) 08150612.3

(51) Int. Cl. H01L 21/4763; H01L 21/316

(52) U.S. Cl. 438/678; 106/287.18; 257/E21.495

(57) ABSTRACT

The invention relates to a solution for the deposition of barrier layers on metal surfaces, which comprises compounds of the elements nickel and molybdenum, at least one first reducing agent selected from among secondary and tertiary cyclic aminoboranes and at least one complexing agent, where the solution has a pH of from 8.5 to 12.

The present invention relates to a solution for the electroless deposition of barrier layers. The present invention further relates to a process for the deposition of barrier layers. In particular, the present invention relates to a solution and a process by means of which the barrier layers can be deposited without prior activation of the metal surface.

Increasing wiring density and speed requirements for microelectronic components have brought about a change in the interconnects wiring material from conventional aluminum (alloys) to copper (Cu). The use of copper takes account of the desire for an increasing total resistance of the interconnects resulting from this wiring density.

However, the use of Cu as wiring material requires, due to its high diffusion activity in the substrate (silicon) or insulating materials (e.g. SiO₂), the use of diffusion barriers. These diffusion barriers are used underneath the Cu wiring to protect the insulating material and as bonding agent between insulation layer and wiring layer.

At the same time, the high cycle frequencies during operation of these components necessitate an increase in the current densities which can result in material separation of the electric conductor material in the wiring. This phenomenon, which is referred to as electromigration, leads to high failure densities of the components, which greatly impairs their performance.

A standard process for producing copper-wired components is the Damascene method. Here, the structures such as interconnects and vias are produced in the insulation layer by lithographic processes and subsequent dry etching processes and are subsequently filled with copper. Chemomechanical polishing (CMP) is used for planarizing the wiring structures.

The metal layers of Co and Ni or Co and Ni alloys are deposited on copper interconnects and serve as barrier layers for the diffusion of copper into adjoining SiO₂ layers. There are two methods for the electroless deposition on copper:
a) The copper metallization is activated by means of palladium nuclei before the deposition process. The subsequent electroless nickel deposition process is usually carried out at temperatures above about 50° C. Hypophosphite is used as reducing agent.
b) The deposition of metal is carried out without prior activation of the copper surface. This is achieved by the use of aminoboranes (DMAB) as reducing agents. The temperatures in this method are from about 80° C. to 90° C. and therefore significantly higher than in deposition using Pd activation.

The latter process gives better quality barrier layers since palladium has an adverse effect on the electrical properties of the semiconductor components but has hitherto had some process engineering disadvantages.

Temperature fluctuations have a direct influence on the deposition rate and the starting behavior of the deposition process. A uniform layer thickness over the entire wafer can therefore be achieved only if the temperature is kept exactly constantly. At high temperatures in a plant, this is difficult and can be achieved only with a large outlay. Particularly in the case of tank plants in which the process chamber has to be opened for loading with a wafer, a temperature drop of about 10° C. takes place within a few seconds if the process is operated at a starting temperature of 85° C.-90° C. Ensuring a uniform temperature is all the more important and difficult the larger the wafer.

U.S. Pat. No. 4,002,778 describes the deposition of layers comprising Ni and B with the aid of dimethylaminoborane (DMAB).

US 2003/0113576 A1 describes the electroless deposition of binary, ternary or quaternary layers comprising nickel or cobalt, e.g. NiB, NiBP, NiCrB, NiCrBP, NiMoB, NiMoBP, NiWP, NiWBP, NiMNB, NiMnBP, NiTcB, NiTcBP, NiReB or NiReBP. The solutions for electroless deposition comprise DMAB as first reducing agent, with diethylaminoborane and morpholine-borane being mentioned as alternatives, and a second reducing agent such as hypophosphite.

WO 2004/099466 A2 discloses the deposition of ternary layers, in particular CoWP, without prior activation. Here, the copper surface is treated with a reducing agent such as hypophosphite or aminoborane, preferably hypophosphite, at elevated temperature before deposition of the layer.

Proceeding from the abovementioned prior art, it is an object of the present invention to provide a solution and a process for the deposition of barrier layers, which can be used at reduced temperature without palladium activation. A further object of the present invention is to avoid a separate reduction step before the actual deposition.

This object is achieved by a solution for the deposition of barrier layers on metal surfaces, which comprises:
compounds of the elements nickel and molybdenum,
at least one first reducing agent selected from among secondary and tertiary cyclic aminoboranes and
at least one complexing agent,
   where the solution has a pH of from 8.5 to 12.

When the solution according to the invention is used, the electroless deposition of the barrier layers can be carried out at considerably lower temperatures. These are easier to control, more economical to maintain and have a positive effect on the operating lives of the deposition baths.

As first reducing agent, use is made of a secondary or tertiary cyclic aminoborane, with secondary aminoboranes being preferred. The cyclic aminoboranes can be saturated, unsaturated or aromatic, with the saturated aminoboranes being preferred. The cyclic aminoboranes can be isocyclic or heterocyclic, with the heterocyclic aminoboranes being preferred. For the purposes of the present invention, isocyclic means that, apart from the boron-bound nitrogen, there are no further heteroatoms present in the ring. For the purposes of the present invention, heterocyclic means that at least one further heteroatom in addition to the boron-bound nitrogen is present in the ring. Preferred heteroatoms are, for example, N, O or S, without these constituting a restriction.

Examples of isocyclic aminoboranes are piperidine-borane or pyrrolidine-borane. Examples of saturated heterocyclic aminoboranes are piperazine-borane C₄H₁₀N₂BH₃, imidazole-borane C₃H₄N₂BH3 and morpholine-borane C₄H₉NOBH₃. Examples of unsaturated heterocyclic aminoboranes are pyridine-borane C₅H₅NBH₃ and 2-picoline-borane C₆H₈NBH_{3.}

Preferred aminoboranes are saturated heterocyclic amine-boranes. Particular preference is given to morpholine-borane since it is relatively stable and has a low toxicity and also gives a particularly uniform deposit.

In a preferred embodiment, the solution comprises at least one second reducing agent. As second reducing agent, it is possible to use a further boron-comprising reducing agent or a boron-free, other reducing agent. Examples of the second reducing agent are further aminoboranes, phosphorus-comprising reducing agents and hydrazines, without being restricted thereto.

Examples of aminoboranes are dimethylaminoborane (DMAB), diethylaminoborane (DEAB) or other dialkylaminoboranes. Further examples are ethylenediamine-borane H₂NCH₂CH₂NH₂BH3, ethylenediamine-bisborane H₂NCH₂CH₂NH₂(BH3)₂, t-butylamine-borane (CH₃)₃CNH₂BH3 and methoxyethylamine-borane H₃CON(C₂H₅)₂BH₃.

Examples of phosphorus-comprising reducing agents are phosphinic acid or salts thereof. Salts of phosphinic acid are, for example, ammonium phosphinates, alkali metal or alkaline earth metal phosphinates such as sodium, lithium, potassium, magnesium or calcium phosphinate or transition metal phosphinates such as nickel phosphinate, and mixtures thereof.

Examples of hydrazine compounds are hydrazine, hydrazine hydrate, hydrazine sulfate, hydrazine chloride, hydrazine bromide, hydrazine dihydrochloride, hydrazine dihydrobromide and hydrazine tartrate. Other hydrazine-forming compounds are 2-hydrazinopyridine, hydrazobenzene, phenylhydrazine, hydrazine-N,N-diacetic acid, 1,2-diethylhydrazine, monomethylhydrazine, 1,1-, 1,2-dimethylhydrazine, 4-hydrazinobenzenesulfonic acid, hydrazinecarboxylic acid, 2-hydrazinoethanol, semicarbazide, carbohydrazide, aminoguanidine hydrochloride, 1,3-diaminoguanidine monohydrochloride and triaminoguanidine hydrochloride. The latter form hydrazine as reaction product.

Other second reducing agents can be sulfites, bisulfites, hydrosulfites, metabisulties and the like. Further second reducing agents are dithionates and tetrathionates. Others are thiosulfates, thioureas, hydroxylamines, aldehydes, glyoxalic acid and reducing sugars. As an alternative, it is also possible to use organometallic compounds such as diisobutylaluminum hydride or sodium bis(2-methoxyethoxy)hydridoaluminate.

Preference is given to phosphorus-comprising compounds as second reducing agent and these can at the same time serve as phosphorus source in the barrier layer deposited. Particular preference is given to phosphinic acid or salts thereof.

The second reducing agent is, if present, usually employed in concentrations of from 0 to 0.5 mol/l, preferably from 0.01 to 0.3 mol/l, particularly preferably from 0.05 to 0.15 mol/l.

A constituent of the solution according to the invention is a nickel compound as source of nickel ions. The nickel compounds are added to the solution either as inorganic nickel compounds such as hydroxides, chlorides, sulfates or other inorganic salts which are soluble in the solvent. As an alternative, it is possible to use nickel complexes with organic carboxylic acids, e.g. acetates, citrates, lactates, succinates, propionates, hydroxyacetates, EDTA or others, or mixtures thereof. Ni(OH)₂ can be used when relatively high concentrations of Cl⁻ or other anions are to be avoided. In a preferred embodiment, nickel is used in a concentration of from 0.001 to 0.5 mol/l, preferably from 0.005 mol/l to 0.3 mol/l, more preferably from 0.01 mol/l to 0.2 mol/l, particularly preferably from 0.05 mol/l to 0.1 mol/l.

A further constituent of the solution according to the invention is a molybdenum compound as source of molybdenum ions as refractory metal. Examples of molybdenum compounds are MoO₃, molybdic acid or salts thereof, in particular with ammonium, tetraalkylammonium and alkali metal salts or mixtures thereof, without being restricted thereto.

In a preferred embodiment, molybdenum is used in a concentration of from 10⁻⁴ to 1 mol/l, preferably from 0.0005 mol/l to 0.1 mol/l, more preferably from 0.001 mol/l to 0.01 mol/l, particularly preferably from 0.003 mol/l to 0.006 mol/l.

Apart from the metals Ni and Mo, it is possible for further metals to be comprised, but preference is given to no further metal ions in addition to nickel and molybdenum being present in the solution, i.e. the solution preferably comprises metal ions which consist of nickel and molybdenum.

The solution comprises one or more complexing agents in order to keep the nickel ions in solution. Owing to the basic pH, the nickel ions tend to form hydroxides which precipitate from the solution. Suitable complexing agents are, for example, citric acid, maleic acid, glycine, propionic acid, succinic acid, lactic acid, diethanolamine, triethanolamine and ammonium salts such as ammonium chloride, ammonium sulfate, ammonium hydroxide, pyrophosphate and mixtures thereof. Preferred complexing agents are hydroxycarboxylic acids. The complexing agent is usually employed in a concentration of from 0.001 mol/l to 1 mol/l, preferably from 0.005 mol/l to 0.5 mol/l, more preferably from 0.01 to 0.3 mol/l, more preferably from 0.1 to 0.25 mol/l, particularly preferably from 0.15 mol/l to 0.2 mol/l.

Furthermore, it is also possible to employ other complexing agents such as ethylenediaminetetraacetic acid (EDTA), hydroxyethylethylenediaminetriacetic acid (HEDTA), nitrilotriacetic acid (NTA). These are usually added in an amount of from 0 to 0.05 g/l, preferably from 0.001 to 0.02 g/l, particularly preferably from 0.005 to 0.01 g/1.

The solution can further comprise surfactants. Preferred surfactants are anionic surfactants or nonionic surfactants. Examples of anionic surfactants are alkylphosphonates, alkyl ether phosphates, alkylsulfates, alkyl ether sulfates, alkylsulfonates, alkyl ether sulfonates, carboxylic ethers, carboxylic esters, alkylarylsulfonates and sulfosuccinates. Examples of nonionic surfactants are alkoxylated alcohols, ethylene oxide-propylene oxide (EO/PO) block copolymers, alkoxylated fatty acid esters, glycol ethers and glycerol ethers of polyethylene glycol and polypropylene glycol. A preferred surfactants is polyoxyethylene-sorbitol monolaurate. The surfactant is, if used, usually employed in a concentration of from 1 mg/l to 1000 mg/l, preferably from 10 mg/l to 200 mg/l.

The pH of the solution should be kept as constant as possible during deposition. Customary buffer solutions are suitable here. These can comprise, for example, organic amines such as pyridine or pyrrolidine, methylamines, dimethylamines, trimethylamines, ethylamines, diethylamines, triethylamine, tetramethylammonium hydroxide (TMAH), tetraethylammonium hydroxide (TEAH), tetrapropylammonium hydroxide (TPAH), tetrabutylammonium hydroxide (TBAH), aniline or toluidine.

As an alternative, it is possible to use salts of a strong base and a weak acid, e.g. alkali metal or alkaline earth metal acetates, propionates, carbonates or the like. The buffers are preferably used in a concentration of from 0 to 1 g/l, in particular from 0.01 to 0.5 g/l, particularly preferably from 0.005 to 0.15 g/1.

The pH of the solution is in the range from 8.5 to 12. Below a pH of 8.5, a rough surface having a cauliflower-like structure is obtained. Above a pH of 12, considerable evolution of H₂ and precipitation of nickel hydroxides is observed. The pH is preferably from 9 to 11.5, particularly preferably from 10.5 to 11.5.

Apart from the abovementioned components, further customary additives such as stabilizers, accelerators or brighteners or levelers can be added. The additives are usually employed in concentrations of from 0 to 1 g/l, preferably from 0.01 to 0.5 g/l, particularly preferably from 0.05 to 0.15 g/l. Small concentrations of Pb, Sn, As, Sb, Se, S and Cd can also serve as stabilizers.

A preferred additive which can also be used for other solutions for the deposition of barrier layers is N,N-dimethyldithiocarbamylpropylsulfonic acid (DPS). DPS is also suitable, for example, for the deposition of other barrier layers comprising Co or Ni. The use of DPS enables particularly smooth barrier layers to be produced.

A particularly preferred solution comprises:
the nickel compound in an amount of from 0.01 to 0.2 mol/1
the molybdenum compound in an amount of from 0.001 to 0.01 mol/1
the complexing agent in an amount of from 0.01 to 0.3 mol/l
the first reducing agent in an amount of from 0.005 to 0.05 mol/l
the second reducing agent in an amount of from 0.1 to 0.3 mol/l.

Furthermore, the molar ratio of the nickel compound to the at least one complexing agent in the solution is preferably set in the range from 1:1 to 1:2.

A further aspect of the present invention is a process for producing barrier layers by electroless deposition on metal surfaces of semiconductor substrates, which comprises
a) preparation of a solution comprising a compound of an element selected from among Ni and Co, a compound of an element selected from among Mo, W and Re and a first reducing agent selected from among secondary and tertiary cyclic aminoboranes,
b) setting of the pH of the solution to from 8.5 to 12,
c) setting of the temperature of the solution to from 50° C. to 85° C.
d) contacting of the metal surface with the solution at a temperature of from 50 to 85° C., resulting in deposition of a layer comprising an element selected from among Ni and Co and an element selected from among Mo, W and Re on the semiconductor substrate.

The process is particularly suitable for the electroless deposition of nickel- or cobalt-comprising barrier layers on metal surfaces of integrated circuits comprising copper. As refractory metals, it is possible to use Mo, W or Re. The electroless deposition process is suitable for depositing barrier layers on metal substrates, in particular copper-comprising substrates, which do not require catalytic activation of the metal surface before the deposition step.

Suitable nickel and cobalt compounds have been described above or are known from the prior art cited at the outset or from WO 2006/044990. In particular, layers of NiWB, NiWPB, NiMoB, NiMoPB, NiReB, NiRePB, CoWB, CoWPB, CoMoB, CoMoPB, CoReB and CoRePB can be deposited on metal surfaces by means of the process of the invention, without the process being restricted thereto. The abovementioned nickel compounds can likewise advantageously be used as corresponding cobalt compound. The same applies to the molybdenum compounds, whose corresponding tungsten and rhenium compounds can likewise be used as preferred tungsten or rhenium source. Combinations of nickel and cobalt and also combinations of the refractory metals Mo, W and Re are also conceivable.

Here, the barrier layer is applied by bringing the solution into contact with a structured substrate which has vias and trenches which are filled with a metal, for example copper. Contacting can here be carried out, for example, by means of dipping, spraying or other customary techniques.

The electroless deposition bath can be used in continuously operated deposition processes in which the bath is used for treating a multiplicity of substrates. The reactants consumed have to be replaced and the accumulated (by-) products have to be removed, which requires regular replacement of the baths. The possibility of deposition at relatively low temperatures enables the operating lives of the baths to be considerably prolonged, as a result of which the baths can be used for a significantly longer time than has been possible when using conventional baths.

As an alternative, the deposition solution can be employed in the form of a “use and dispose” deposition process. Here, the bath is discarded after treatment of the substrate.

The deposition is carried out at temperatures of from 50° C. to 85° C. Below 50° C., the deposition cannot be operated economically because of the low reaction rate. Above 85° C., the reaction starts extremely quickly and the deposition occurs too quickly so that there is increased deposition on the dielectric, as a consequence of which short circuits can occur in the substrate. Preference is given to deposition at temperatures from 50° C. to 75° C., more preferably from 52° C. to 70° C., particularly preferably from 55° C. to 65° C.

The starting behavior of a solution for electroless deposition is a particularly important parameter and indicates the time delay after immersion before deposition commences. The start time should be very short (less than 10 s). Only in this way can a uniformly thick layer be produced on a wafer. The uniformity is particularly important for the new generation of wafers having a diameter of 300 mm.

A further reason why the deposition should commence quickly is that in the case of a long delay it is possible for secondary reactions of the nickel deposition solution with the copper metallization to be coated to take place and these can adversely affect or damage the copper surface, e.g. by etching.

Studies have shown that only cyclic secondary or tertiary aminoboranes are able to achieve very good deposition results at low temperatures, in particular at temperatures of from 60 to 65° C.

The deposition rate of the barrier layer on the substrate is preferably set so that it is greater than 10 nm/min. Particular preference is given to deposition rates of from 10 to 50 nm/min.

All documents cited are incorporated by reference into the present patent application. All amounts (percentages, ppm, etc.) are by weight, based on the total weight of the mixture, unless indicated otherwise.

The following examples illustrate the present invention without restricting it thereto.

### EXAMPLES

The following examples demonstrate that the use of morpholine-borane (MPB) as reducing agent in the NiMoP deposition solution is associated with a significant reduction in temperature in the deposition process compared to dimethylaminoborane (DMAB).

### Example 1

A solution having the following composition was prepared:

| Component | Content (mol/l) | |
|---|---|---|
| Citric acid | 0.1 | |
| Maleic acid | 0.025 | |
| Boric acid | 0.25 | |
| HEDTA | 0.007 | |
| NiSO₄ | 0.06 | |
| MoO₃ (as molybdate) | 0.001 | |
| Phosphinic acid | 0.1 | |
| MPB | 0.02 | |
| Tween20 | 100 | mg/l |

| | |
|---|---|
| NaOH | about 0.8 |
| Water | balance |

The pH of the solution was set to 10-10.5 by means of NaOH.

The starting behavior of the deposition of NiMoP at various temperatures was examined by means of electrochemical measurements. For this purpose, a wafer was dipped into the deposition solution and the open circuit potential (OCP) was measured as a function of time. The commencement of deposition was shown by a significant step increase in the potential.

The results are shown in table 1.

Deposition occurred particularly quickly at 65° C. In this case, it started immediately on immersion. Deposition was also possible at 50 and 55° C. Scanning electron micrographs showed a uniform and smooth deposit.

### Example 2

A solution having the following composition was prepared:

| Component | Content (mol/l) | |
|---|---|---|
| Citric acid | 0.1 | |
| Maleic acid | 0.025 | |
| Boric acid | 0.25 | |
| HEDTA | 0.007 | |
| NiSO₄ | 0.06 | |
| MoO₃ (as molybdate) | 0.001 | |
| Phosphinic acid | 0.1 | |
| MPB | 0.01 | |
| DMAB | 0.01 | |
| Tween20 | 100 | mg/l |

| | |
|---|---|
| NaOH | about 0.8 |
| Water | balance |

The pH of the solution was set to 10-10.5 by means of NaOH.

The starting behavior of the deposition of NiMoP was again examined at various temperatures. The results are shown in table 1 in which the start times at the respective temperatures are recorded.

It can be seen that the starting behavior is considerably slower than when using the solution comprising morpholine-borane. Even at a temperature of 65° C., deposition commenced only after an undesirably long start phase of over 10 s.

### Example 3

### Comparative Example

A solution having the following composition was prepared:

| Component | Content (mol/l) | |
|---|---|---|
| Citric acid | 0.1 | |
| Maleic acid | 0.025 | |
| Boric acid | 0.25 | |
| HEDTA | 0.007 | |
| NiSO₄ | 0.06 | |
| MoO₃ (as molybdate) | 0.001 | |
| Phosphinic acid | 0.1 | |
| DMAB | 0.02 | |
| Tween20 | 100 | mg/l |

| | |
|---|---|
| NaOH | about 0.8 |
| Water | balance |

The pH of the solution was set to 10-10.5 by means of NaOH.

The starting behavior of the deposition of NiMoP was again examined at various temperatures. The results are shown in table 1.

It can be seen that the starting behavior is much slower than when using the solution comprising morpholine-borane. At a temperature of 65° C., deposition commenced only after an undesirably long start phase of well over 10 s. At 60° C., the start phase took a number of minutes, while at 50 and 55° C. no commencement of deposition could be observed.

TABLE 1

| | | | | | Comparative | |
|---|---|---|---|---|---|---|
| Temperature | Example 1 | | Example 2 | | example 3 | |
| 50° C. | 85.4 | s | 159.1 | s | >240 | s |
| 55° C. | 44.4 | s | 94.6 | s | >240 | s |
| 60° C. | 11.1 | s | 52.2 | s | 176.5 | s |
| 65° C. | <1 | s | 14.1 | s | 22.4 | s |

### Example 4

Three solutions L1, L2 and L3 having the following compositions were prepared:

| | Content | | Content | | Content | |
|---|---|---|---|---|---|---|
| Component | (mol/l) (L1) | | (mol/l) (L2) | | (mol/l) (L3) | |
| Citric acid | 0.18 | | 0.1 | | 0.1 | |
| Maleic acid | 0.025 | | 0.03 | | 0.03 | |
| Boric acid | 0.25 | | 0.3 | | 0.3 | |
| HEDTA | 0.007 | | 0.007 | | 0.007 | |
| NiSO₄ | 0.06 | | 0.07 | | 0.07 | |
| MoO₃ (as molybdate) | 0.01 | | 0.008 | | 0.004 | |
| Phosphinic acid | 0.1 | | 0.1 | | 0.1 | |
| MPB | | | 0.02 | | 0.02 | |
| DMAB | 0.01 | | | | | |
| Tween20 | 100 | mg/l | 100 | mg/l | 100 | mg/l |

| | | | |
|---|---|---|---|
| Base | about 0.9 | about 0.8 | about 0.8 |
| | (TMAH) | (NaOH) | (NaOH) |
| Water | balance | balance | balance |
| pH | 11 | 10.5 | 10.5 |

The pH of the solution was set by means of NaOH or TMAH. Barrier layers were deposited as in example 1 and their composition was subsequently measured by means of XPS. The results are shown in table 2. The results show that despite the significantly reduced temperature, barrier layers having a suitable composition can be deposited by means of the process of the invention.

TABLE 2

| | Molybdate conc. | | |
|---|---|---|---|
| Temperature | (mol/l) | P/Ni ratio | Mo/Ni ratio |
| 90° C. (L1) | 0.01 | 0.1 | 0.15 |
| 60° C. (L2) | 0.008 | 0.1 | 0.3 |
| 60° C. (L3) | 0.004 | 0.3 | 0.2 |

1. A solution for the deposition of barrier layers on metal surfaces, which comprises:
compounds of the elements nickel and molybdenum,
at least one first reducing agent selected from among secondary and tertiary cyclic aminoboranes,
at least one second reducing agent selected from among phosphinic acid and, a salt thereof, and
at least one complexing agent
where the solution has a pH of from 8.5 to 12.

2. (canceled)

3. The solution according to claim 1, wherein the first reducing agent is a heterocyclic aminoborane.

4. The solution according to claim 1, wherein the at least one complexing agent is a hydroxycarboxylic acid.

5. The solution according to claim 1 comprising:
the nickel compound in an amount of from 0.01 to 0.2 mol/1
the molybdenum compound in an amount of from 0.001 to 0.01 mol/1
the complexing agent in an amount of from 0.01 to 0.3 mol/1
the first reducing agent in an amount of from 0.005 to 0.05 mol/l and
the second reducing agent in an amount of from 0.1 to 0.3 mol/l.

6. The solution according to claim 1, wherein the molar ratio of the nickel compound to the at least one complexing agent is from 1:1 to 1:2.

7. A method for the electroless deposition of layers on metal surfaces of integrated circuits comprising copper which comprises contacting said metal surface with the solution according to claim 1.

8. A process for producing barrier layers by electroless deposition on metal surfaces of semiconductor substrates, which comprises
a) preparation of a solution comprising a compound of an element selected from among Ni and Co, a compound of an element selected from among Mo, W and Re, a first reducing agent selected from among secondary and tertiary cyclic aminoboranes and a second reducing agent,
b) setting of the pH of the solution to from 8.5 to 12,
c) setting of the temperature of the solution to from 50° C. to 85° C., and
d) contacting of the metal surface with the solution at a temperature of from 50 to 85° C., resulting in deposition of the barrier layer on the semiconductor substrate.

9. The process according to claim 8, wherein the temperature is from 55° C. to 65° C.

10. The process according to claim 8, wherein the deposition rate is greater than 10 nm/min.

11. The process according to claim 8, wherein no catalytic activation of the metal surface occurs before the metal surface is brought into contact with the solution.

12. The process according to claim 8, wherein the metal surface comprises copper.

13. The process according to claim 8, wherein the second reducing agent is selected from among phosphinic acid and a salt thereof.
